(19) United States
(12) Patent Application Publication
(10) Pub. No.: US 2007/0272963 A1
(43) Pub. Date: Nov. 29, 2007

(54) Semiconductor device and method for fabricating the same

(75) Inventor: Takeshi Kishida, Tokyo (JP)

Correspondence Address: Paul J. Esatto, Jr.;Scully, Scott, Murphy & Presser, P.C., Suite 300, 400 Garden City Plaza, Garden City, NY, 11530, US

(73) Assignee: Elpida Memory, Inc., Tokyo (JP)

(21) Appl. No.: 11/807,494

(22) Filed: May 29, 2007

(30) Foreign Application Priority Data
May 29, 2006 (JP) 2006-148201

(51) Int. Cl. H01L 29/94; H01L 21/8242

(52) U.S. Cl. 257/301; 438/243; 257/E27.086

(57) ABSTRACT

A semiconductor device having in a deep hole formed in a first interlayer insulating film a memory cell region that comprises a plurality of capacitors having a lower electrode 229 composed of a crown structure having an outside face and inner face, a first upper electrode 231 facing the outside face of the lower electrode, and a dielectric and a second upper electrode extending from the inner face of the lower electrode to the surface of a first interlayer insulating film other than the deep hole; wherein the first upper electrode is connected to the second upper electrode by connecting a first upper electrode 227 formed on the inner wall of the deep hole to the wiring 241a via a conductor film 224 and a conductor plug 236a, and connecting a second upper electrode 231 to be a plate to a wiring 241a via a conductor plug 239a.

### BACKGROUND OF THE INVENTION

1. Field of the Invention

The present invention relates to a semiconductor device having a capacitor such as a DRAM (dynamic random access memory), and a method for fabricating the same. More specifically, the present invention relates to a capacitor structure suited for avoiding the problem of the collapse of lower electrodes when the lower electrodes having a crown structure are formed, and a method for fabricating the same.

2. Related Art

In recent years, the capacity of a semiconductor device has been increasingly elevated. Particularly in a DRAM, a gigabit-class memory wherein minimum processing dimension is 100 nm has been commercialized, and further, a DRAM corresponding to the minimum processing dimension of 90 nm or less has been developed. Accompanying such a miniaturization of elements, the securement of a desired capacity of a capacitor, which is an essential component of a DRAM, has become difficult.

To overcome such difficulty, a capacitor having a crown structure, fabricating by steps of forming a deep hole in an insulating film, forming a cylindrical lower electrode on the inner wall of the deep hole and exposing the inner surface and outer wall surface of the cylindrical lower electrode, has been studied. In the crown structure, the area from the inner wall to the outer wall is used as the surface of the lower electrode and as a result, a capacitor area of about twice the area, when only-the inner surface of the cylindrical lower electrode is used, can be secured. Therefore, the advantage wherein about twice as much capacity compared with the capacitor in which the inner surface of the cylindrical lower electrode is only used as the surface of the lower electrode can be obtained.

However, the fabrication of a conventional crown structure has the following problems. FIGS. 1(A), 1(B), and 1(C) schematically show the process for fabricating a conventional crown structure. First, as shown in FIG. 1(A), capacitive contact plugs 102 are formed in predetermined regions of lower interlayer insulating film 101, and then, a first interlayer insulating film composed of silicon nitride film 103 and thick silicon oxide film 104 was deposited. Next, as shown in FIG. 1(B), deep holes 105 are opened using lithography and dry etching to expose the surface of the capacitive contact plugs 102, and then, lower electrodes 106 are formed on the inner surfaces of the deep holes. Thereafter, as shown in FIG. 1(C), thick silicon oxide film 104, which have supported the outer wall of the lower electrodes 106 is removed using a hydrofluoric acid (HF) solution. When thick silicon oxide film 104 is removed using this HF solution, lower electrodes 106 cannot be supported, and the mechanical strength thereof is significantly lowered. As a result, the lower electrodes are collapsed by the surface tension of the HF solution, bringing about a pair-bit defect caused by the contact of adjoining lower electrodes with each other.

To avoid the above-described defect, a method for fabricating a capacitor having a crown structure without removing the above-described first interlayer insulating film is disclosed in Japanese Patent Laid-Open No. 10-173148 (Patent Document 1). FIGS. 2(A) to 2(G) illustrate a process for fabricating a crown structure disclosed in an embodiment of Patent Document 1. A method for fabricating a crown structure disclosed in Patent Document 1 will be described below referring to FIG. 2.

First, as shown in FIG. 2(A), capacitive contact plugs 102 are formed in predetermined regions of lower interlayer insulating film 101, and then, a first interlayer insulating film composed of silicon nitride film 103 and thick silicon oxide film 104 was deposited. Deep holes 105 are opened so as to expose the surfaces of the capacitive contact plugs 102. Thereafter, first upper electrodes 107 composed of polycrystalline silicon are formed on the sidewalls of deep holes 105.

Next, as shown in FIG. 2(B), first dielectric 108 composed of a laminated film of tantalum oxide and silicon oxide is deposited on the entire surface, and then, outside lower electrode 109 composed of titanium nitride is deposited on the entire surface. Thereafter, using anisotropic dry etching, outside lower electrode 109 and first dielectric, 108 formed on the surface other than the deep holes and the bottom of the deep holes are removed.

Next, as shown in FIG. 2(C), inside lower electrode 110 composed of polycrystalline silicon is deposited, and the deep holes are filled with photo-resist 111. Photo-resist 111 is formed so that the upper ends thereof are a little lower than the upper surface of the deep holes.

Next, as shown in FIG. 2(D), inside lower electrode 110 composed of polycrystalline silicon and outside lower electrode 109 composed of titanium nitride are etched by dry etching to etch back them to the substantially the same level as the surface of photo-resist 111.

Next, as shown in FIG. 2(E), photo-resist 111 is removed, and second dielectric 112 composed of a laminated film of tantalum oxide and silicon oxide is deposited, and then, second upper electrodes 113 composed of titanium nitride are deposited on the entire surface so as to bury the deep holes and etch back them to the level shown in the drawing.

Next, as shown in FIG. 2(F), second dielectric 112 exposed on the surface is etched by dry etching, and is etched back to the substantially the same level as the surface of second upper electrodes 113. At this time, by simultaneously etching first dielectric 108, the tops of first upper electrodes 107 are exposed.

Next, as shown in FIG. 2(G), third upper electrode 114 composed of titanium nitride is deposited on the, entire surface to connect first upper electrode 107 and second upper electrode 113 with each other. The lower electrode connected to capacitive contact plug 102 is composed of the inside lower electrode 110 composed of polycrystalline silicon and outside lower electrode 109 composed of titanium nitride. Between first upper electrode 107 and outside lower electrode 109, first dielectric 108 composed of a laminated film of tantalum oxide and silicon oxide are formed; and between second upper electrode 113 and inside lower electrode 110, second dielectric 112 composed of a laminated film of tantalum oxide and silicon oxide are formed, to compose capacitors each having a crown structure in the deep holes.

Since the insulating film composing the deep holes is not removed in this known example, there is the advantage of preventing the collapse of lower electrodes.

However, according to the method for fabricating the crown structure disclosed in Patent Document 1, it is extremely difficult to connect first upper electrode 107 formed on the inner walls of the deep holes to third upper electrode 114, and there is a problem that the capacitor structure cannot be composed.

The above-described problem will be explained below referring to FIG. 3.

FIG. 3(A) shows the state after inside lower electrode 110 composed of polycrystalline silicon is deposited and the deep holes are filled with photo-resist 111 in the step shown in FIG. 2(C), and thereafter the photo-resist is removed by etching back using dry etching. Although this step intends to selectively etch back outside lower electrode 109 composed of titanium nitride and inside lower electrode 110 composed of polycrystalline silicon as shown in FIG. 2(D), actually first upper electrode 107 is also etched back at the same time. First upper electrode 107 is composed of polycrystalline silicon as inside lower electrodes 110, and naturally, both first upper electrode 107 and inside lower electrode 110 are etched in the same manner. As a result, first dielectric 108 is protruded, and gaps 115 are formed on the upper parts of first upper electrodes 107.

Next, as shown in FIG. 3(B), when second dielectric 112 is deposited, the gaps 115 are filled with second dielectric 112, resulting in the state wherein an insulating film is formed on the upper parts of first upper electrodes 107. In this state, inside upper electrodes 113 are formed.

Next, as shown in FIG. 3(C), even if second dielectric 112 is etched back, second dielectric 116 remaining in the gaps 115 is formed on the upper parts of first upper electrodes 107, and the top surfaces of first upper electrodes 107 are not exposed.

In the above-described state, as shown in FIG. 3(0), even if third upper electrode 114 is formed, the top surfaces of first upper electrodes 107 are covered with second dielectric 116, and the connection of third upper electrode 114 to first upper electrodes 107 cannot be secured, and the capacitor cannot be realized.

As described above, when a capacitor having a crown structure is formed in deep holes, the securement of the connection of third upper electrode 114 to first upper electrodes 107 becomes the largest technical issue.

### SUMMARY OF THE INVENTION

In view of the above-described problems, an object of the present invention is to provide a semiconductor device having capacitors of a crown structure wherein a first upper electrode is connected to a second upper electrode by an easier method, and a method for fabricating such a semiconductor device.

To achieve the above-described object, the present invention relates to a semiconductor device having a memory cell region that comprises a plurality of capacitors provided in a deep hole formed in a first interlayer insulating film,

wherein said capacitor includes a lower electrode having a crown structure composed of an outer wall face and an inner face, a first upper electrode facing the outer wall face of said lower electrode, a dielectric and a second upper electrode extending from the inner face of said lower electrode to the surface other than said deep hole, and

wherein said first upper electrode is connected to said second upper electrode via at least a first conductor plug that buries a first through-hole formed in said first interlayer insulating film adjacently to said memory cell region.

A semiconductor device of the present invention is characterized by having a capacitor in which said second upper electrode is connected to said first upper electrode by:

connecting said second upper electrode via a second conductor plug that buries a second through-hole provided in a second interlayer insulating film that covers said second upper electrode to wiring provided on said second interlayer insulating film; and

connecting said first upper electrode to a conductor film located at the bottom of said first interlayer insulating film, said conductor film being connected to the first conductor plug that buries the first through-hole formed in said first interlayer insulating film on said conductor film and said second interlayer insulating film laminated on said first interlayer insulating film, and said first conductor plug being connected to said wiring provided on said second interlayer insulating film.

A method for fabricating a semiconductor device of the present invention is a method for fabricating a semiconductor device having a memory cell region that comprises-a plurality of capacitors provided in a deep hole formed in a first interlayer insulating film, including a lower electrode, a dielectric, and an upper electrode, at least comprising steps of:
(1) forming contact plugs in a lower interlayer insulating film at a predetermined location of a memory cell region;
(2) sequentially depositing an insulating film and a conductor film on said lower interlayer insulating film;
(3) removing said insulating film and said conductor film located on the area other than the memory cell region and the adjacent region of said memory cell region;
(4) forming said first interlayer insulating film on the entire surface, and opening a deep hole in said first interlayer insulating film at a predetermined location of the memory cell region to expose the sides of said conductor film and the surfaces of said contact plugs;
(5) forming a first upper electrode on the sidewall of said deep hole so that said first upper electrode is connected to the sides of said conductor film;
(6) forming a first dielectric on the sidewall of said deep hole on which said first upper electrode has been formed;
(7) forming a lower electrode having a crown structure on the inner surface of said deep hole on which said first dielectric has been formed so that said lower electrode is connected to said contact plugs;
(8) forming a second dielectric and a second upper electrode on the inner surface of the deep hole on which the lower electrode has been formed;
(9) removing said second upper electrode around the memory cell region;
(10) forming a second interlayer insulating film on the entire surface;
(11) forming a second through-hole in said second interlayer insulating film at a predetermined location of the memory cell region to expose the surface of said second upper electrode;
(12) forming a first through-hole in said second and first interlayer insulating films at a predetermined location of said adjacent region of the memory cell region to expose the surface of said conductor film;
(13) forming a first conductor plug filling said first through-hole, and a second conductor plug filling said second through-hole; and
(14) forming wiring on said second interlayer insulating film to connect said first conductor plug to said second conductor plug.

In the semiconductor device of the present invention having the above-described configuration, since capacitors having a crown structure are formed in deep holes, about twice as much capacity of the capacitor is obtained compared with a simple deep-hole capacitor wherein the outside surfaces of lower electrodes are not used. Therefore, the depth of the deep holes, which was required to be about 3 μm to achieve a desired capacity by a capacitor having a simple deep-hole structure, can be halved to about 1.5 μm, and the difficulty of dry etching for forming the deep holes can be avoided. Furthermore, since the first upper electrodes are connected to the second upper electrode via through-holes opened in the first interlayer film adjoining the memory cell region, the problem of difficulty in connecting the first upper electrodes to the second upper electrode as described referring to FIG. 3 can be avoided.

According to the method for fabricating a semiconductor device of the present invention having the above-described configuration, since capacitors having a crown structure can be formed in deep holes formed in an insulating film, the removal of the insulating film is not required. Therefore, pair-bit defect caused by the contact of adjoining lower electrodes with each other due to the destruction of the lower electrodes as shown in FIG. 1 can be avoided.

### BRIEF DESCRIPTIN OF THE DRAWINGS

FIGS. 1(A) to 1(C) are a series of sectional views for illustrating conventional problems in the formation of a crown structure;

FIGS. 2(A) to 2(G) are a series of process sectional views for illustrating an example described in Patent Document 1;

FIGS. 3(A) to 3(D) are a series of process sectional views for illustrating problems in an example described in Patent Document 1;

FIG. 4 is a sectional view for illustrating the configuration of a semiconductor device according to Embodiment 1 of the present invention;

FIGS. 5(A) to 5(P) are a series of process sectional views for illustrating a method for fabricating a semiconductor device according to Example 2 of the present invention;

FIGS. 6(A) to 6(E) are a series of process sectional views for illustrating a method for fabricating a semiconductor device according to Example 3 of the present invention; and

FIG. 7 is a bird's-eye view for illustrating the overview of the present invention.

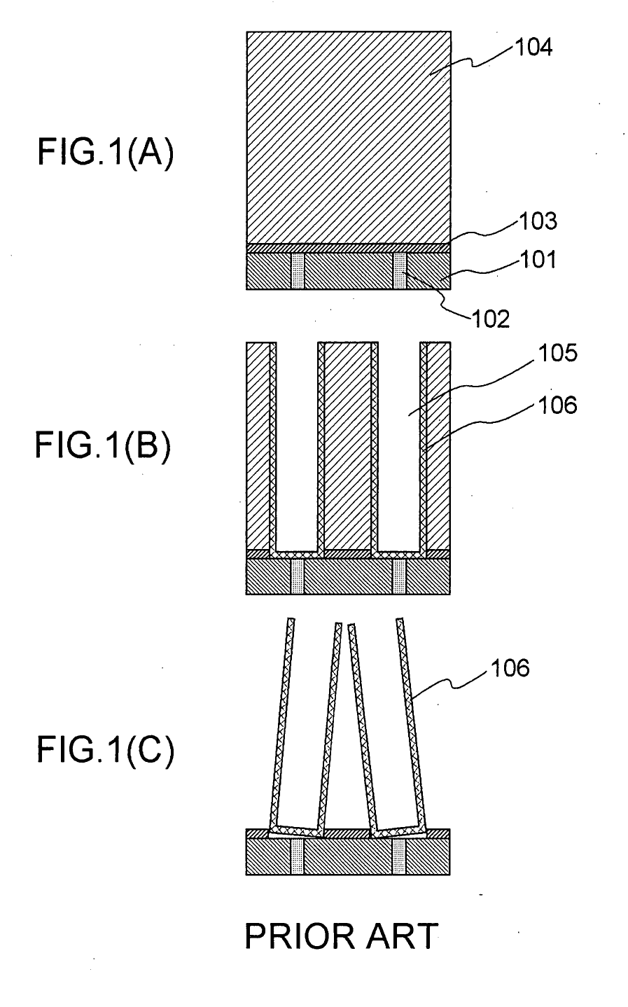

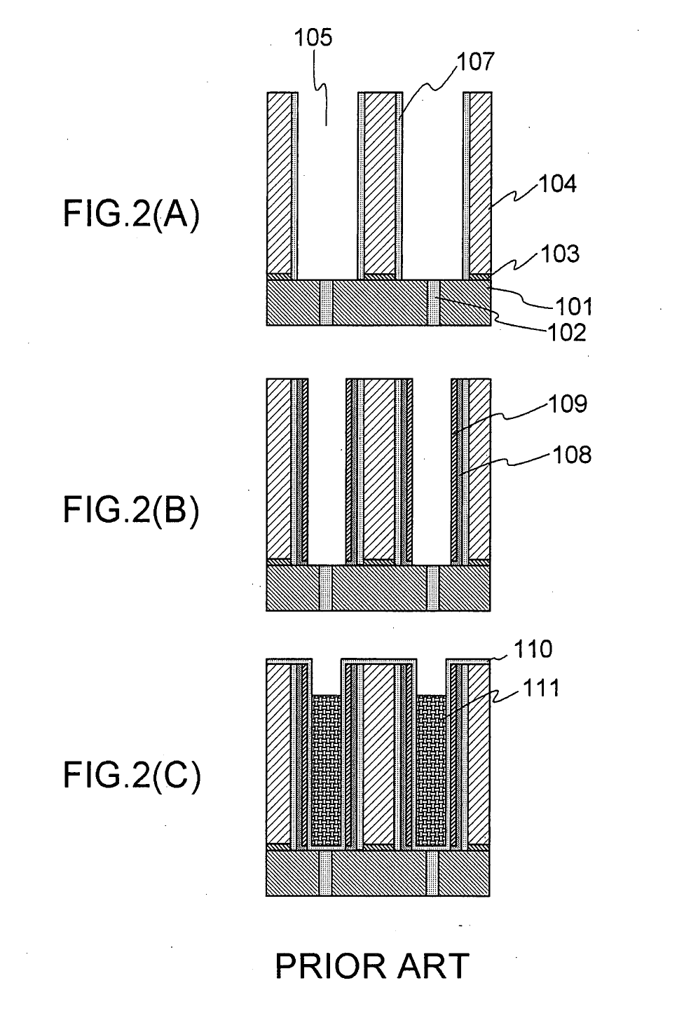

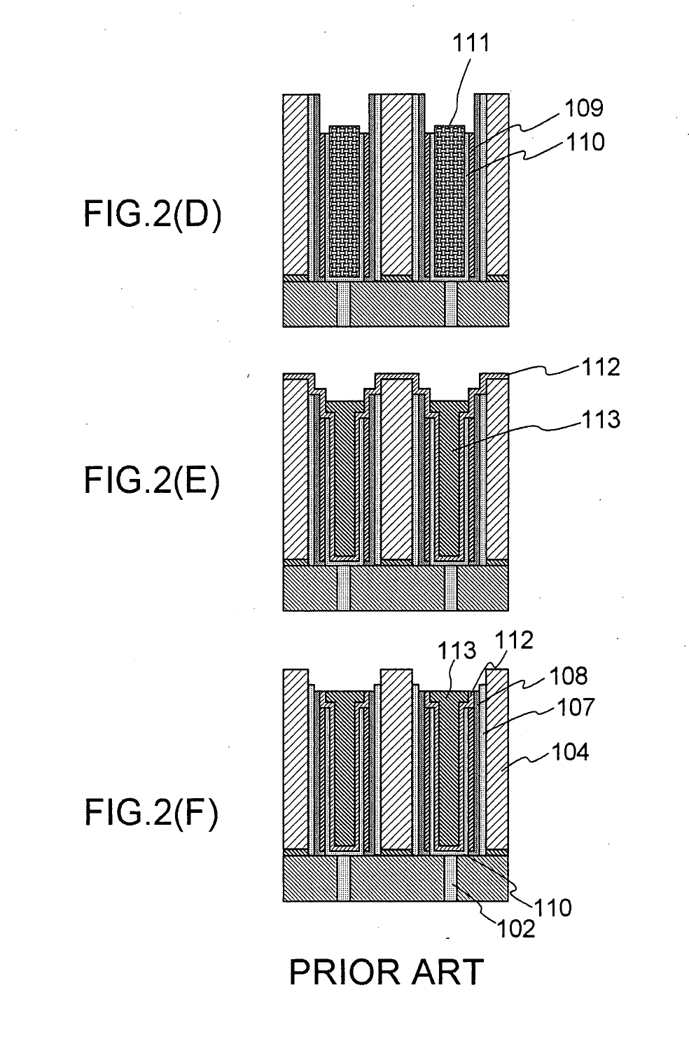

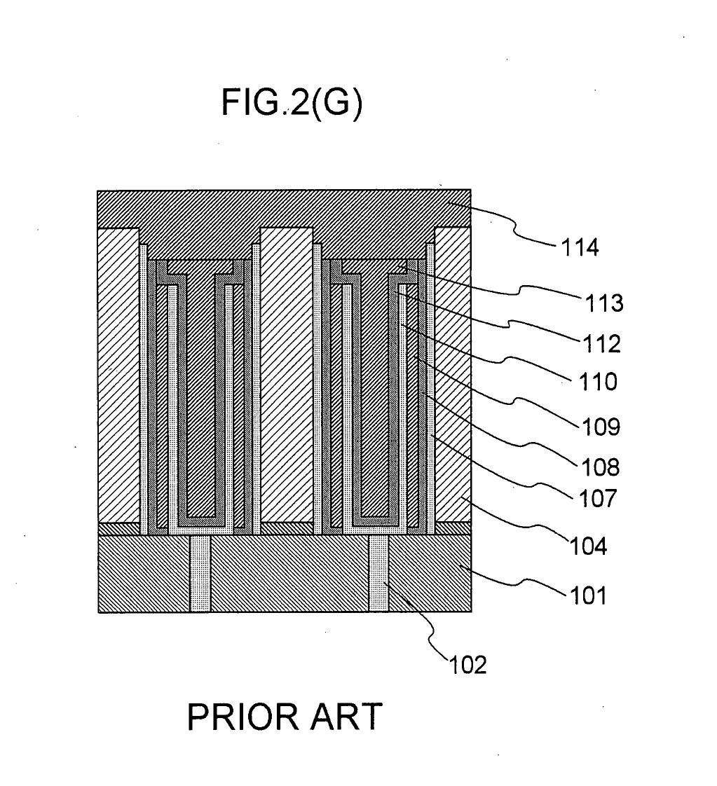

### DESCRIPTION OF THE PREFERRED EMBODIMENTS

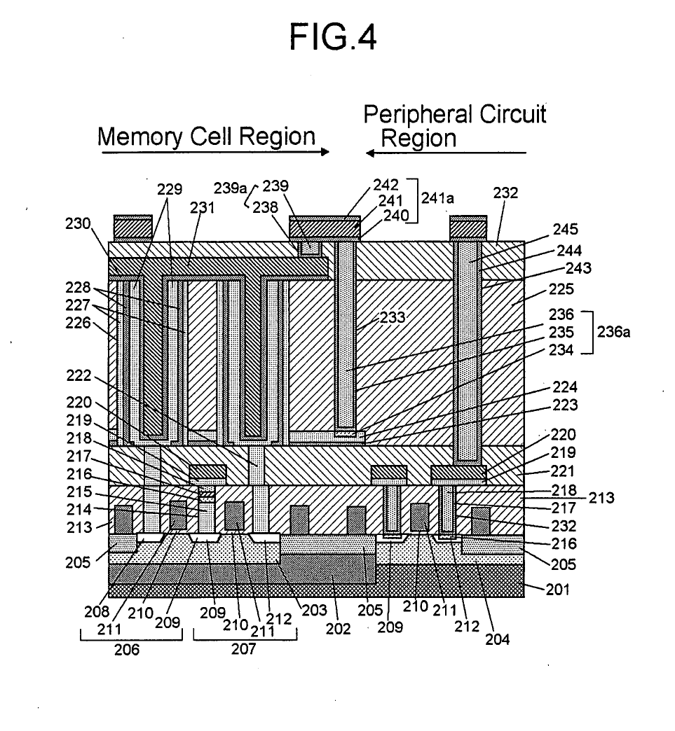

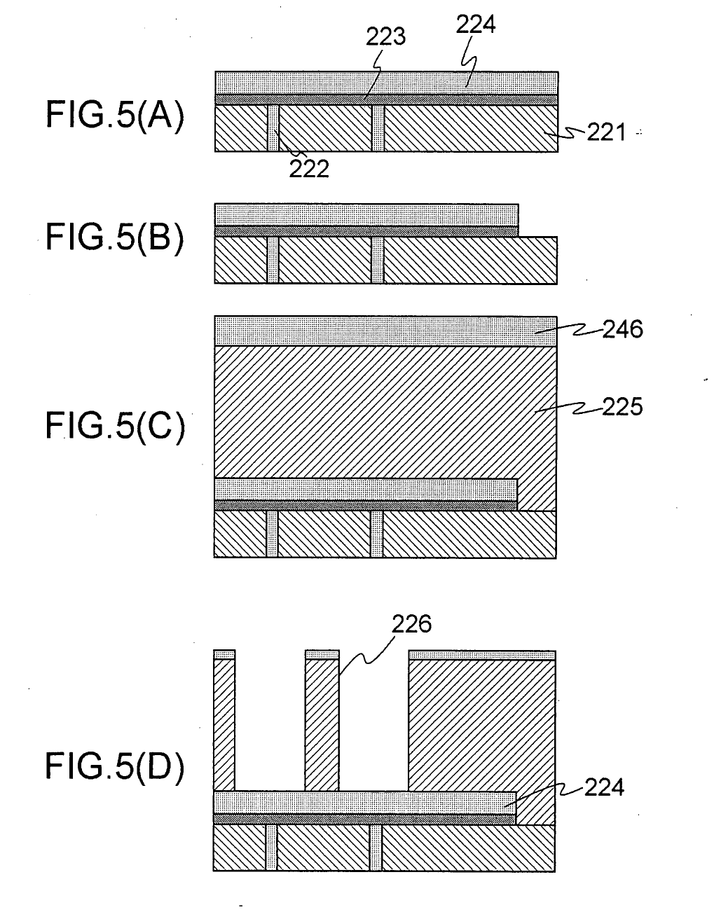

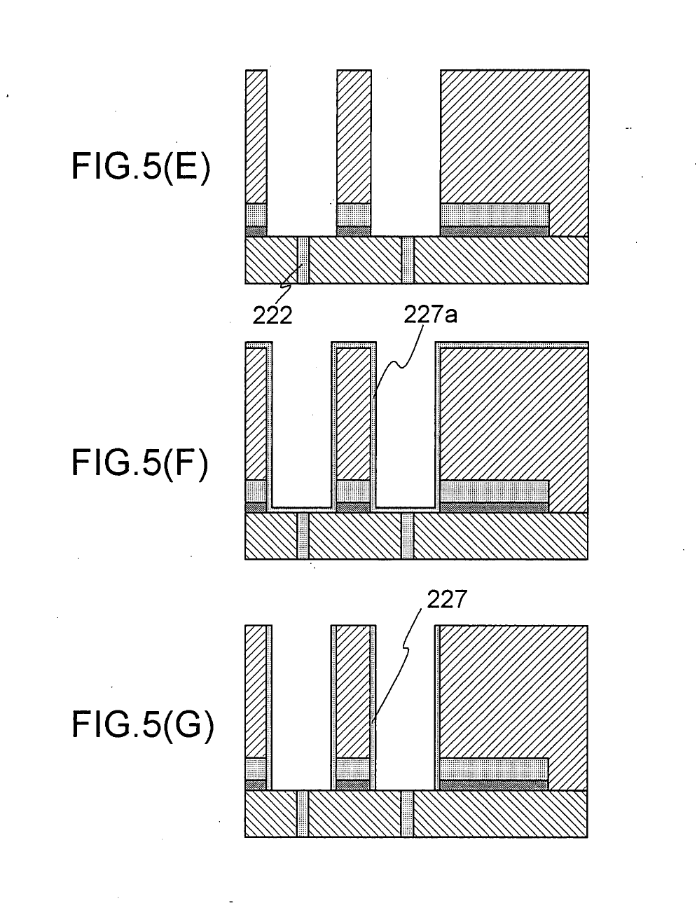

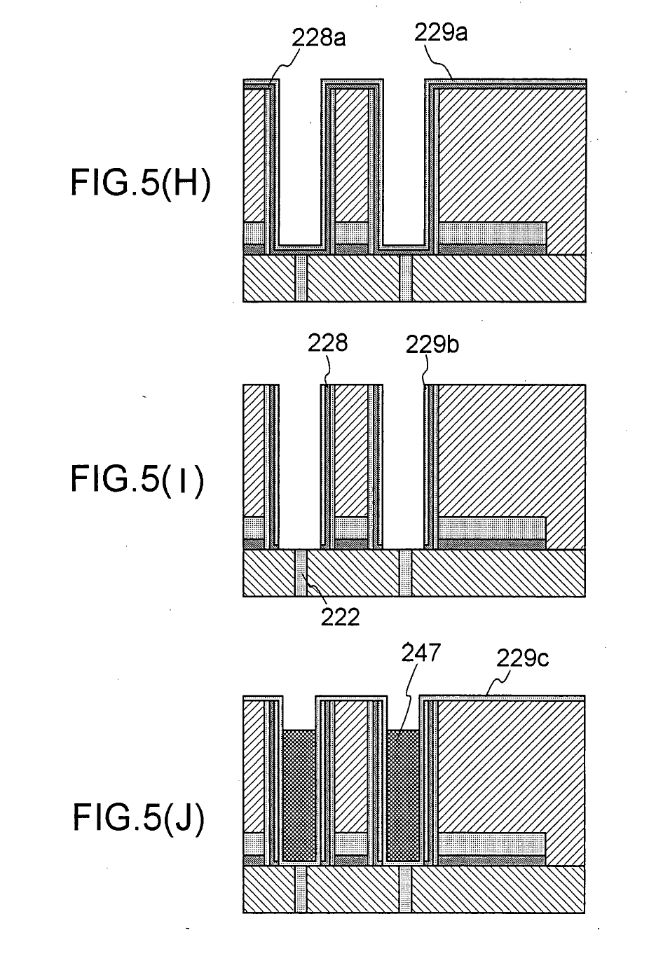

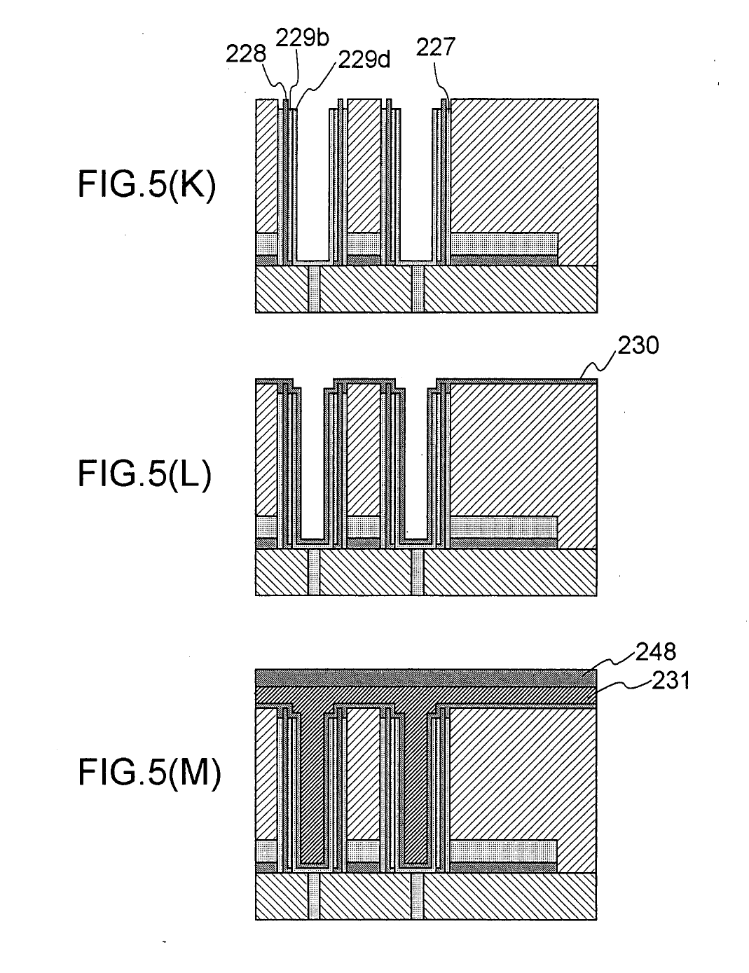

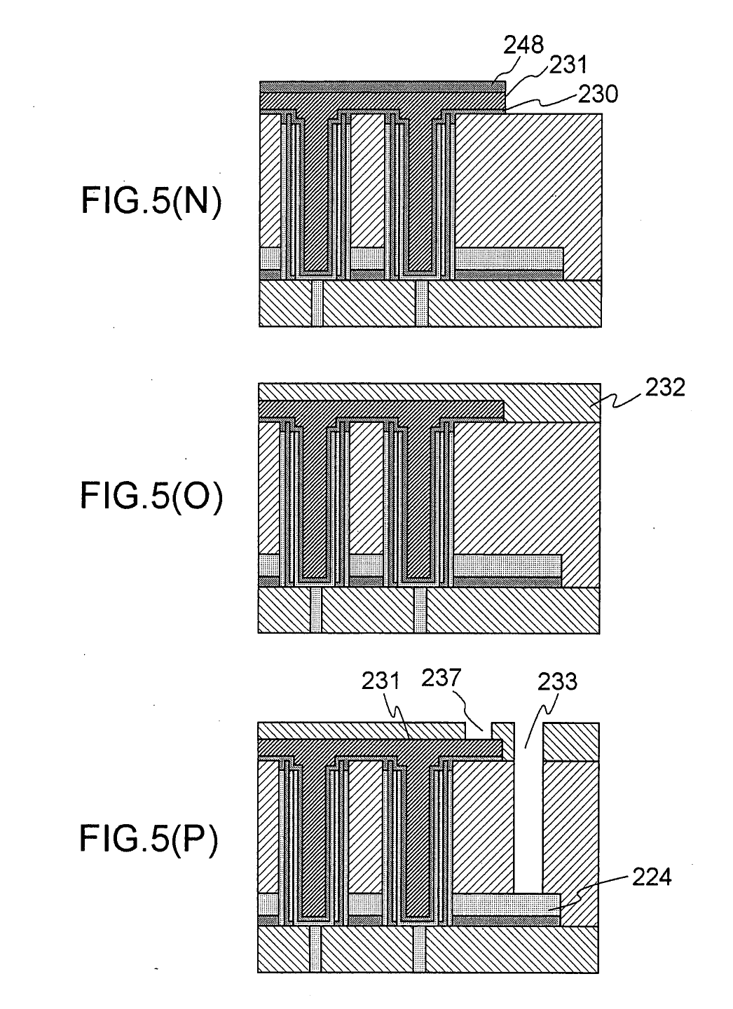

The embodiments of the present invention will be described in detail below referring to FIG. 4, FIGS. 5(A) to 5(p), FIGS. 6(A) to 6(E), and FIG. 7.

### Embodiment 1

First, the configuration of a semiconductor device according to the present invention will be described referring to a sectional view shown in FIG. 4.

In p-type silicon substrate 201; n-well 202 is formed, and first p-well 203 is formed therein. In the region of p-type silicon substrate 201 other than n-well 202, second p-well 204 is formed, and element isolating regions 205 are formed. First p-well 203 and second p-well 204 represent a memory cell region on which a plurality of memory cells are disposed and a peripheral circuit region, respectively, for descriptive purpose. On the first p-well 203, switching transistors 206 and 207 that become word lines in the components of respective memory cells are formed. Transistor 206 is composed of drain 208, source 209, and gate electrode 211 via gate insulating film 210. Transistor 207 is composed of common source 209, drain 212, and gate electrode 211 via gate insulating film 210. Interlayer insulating film 213 having a flat surface is formed so as to cover the transistors.

Contact hole 214 is formed in predetermined regions of insulating film 213 so as to connect to source 209, and contact plug 215 composed of polycrystalline silicon is formed therein. On the surface of contact plug 215, a bit wiring contact plug composed of titanium silicide 216, titanium nitride 217 and tungsten 218. A bit wiring composed of tungsten nitride 219 and tungsten 220 is formed so as to connect to the bit wiring contact plug. Interlayer insulating film 221 having a flat surface is formed so as to cover the bit wiring.

Contact holes are formed in predetermined regions of interlayer insulating film 213 and interlayer insulating film 221 so as to connect to drains 208 and 212 of the transistors, and capacitive contact plugs 222 are formed therein.

A capacitor of a crown structure is formed on capacitive contact plugs 222. On interlayer insulating film 221, insulating film 223 and conductor film 224 are formed so as to run off the memory cell region by the area of a region for forming first through-hole 233. Further, first interlayer insulating film 225 is formed on the entire surface. Deep holes 226 are opened in predetermined locations of first interlayer insulating film 225 so as to penetrate conductor film 224 and insulating film 223, first upper electrodes 227 are formed on the sidewalls of deep holes 226, and are connected to the side of conductor film 224. On the further inside surfaces of first upper electrodes 227, first dielectrics 228 are formed, and on the further inside surfaces of first dielectrics 228, lower electrodes 229 are formed. Lower electrodes 229 are connected to capacitive contact plugs 222. Second dielectric 230 and second upper electrode 231 are formed on the entire surface of the memory cell region comprising the inner surfaces of lower electrodes 229. In a predetermined region of second interlayer insulating film 232 formed over second upper electrode 231, second through-hole 237 is formed, and second conductor plug 239a composed of titanium nitride 238 and tungsten 239 is formed. On second interlayer insulating film 232, wiring 241a composed of titanium nitride 240, aluminum 241, and titanium nitride 242 is formed, and second upper electrode 231 is connected to wiring 241a via second conductor plug 239a.

On conductor film 224 formed adjacent to the memory cell region so as to run off the memory cell region, first through-hole 233 penetrating first interlayer insulating film 225 and second interlayer insulating film 232 is formed, and first conductor plug 236a composed of titanium silicide 234, titanium nitride 235, and tungsten 236 is formed. When conductor film 224 is composed of a metal or metal compound, the formation of titanium silicide 234 is not required. First conductor plug 236a is connected to wiring 241a. Therefore, first upper electrode 227 is connected to second upper electrode 231 via conductor film 224, first conductor plug 236a, wiring 241a, and second conductor plug 239a to compose a capacitor having lower electrodes 229 of the crown structure.

On the other hand, second p-well 204 is provided with a transistor to constitute a peripheral circuit, which is composed of source 209, drain 212, gate insulating film 210, and gate electrode 211. Contact hole 232 is formed in a predetermined region of insulating film 213 so as to be connected to source 209 and drain 212. A contact plug composed of titanium silicide 216, titanium nitride 217, and tungsten 218 is formed, and a first wiring layer composed of tungsten nitride 219 and tungsten 220 is formed thereon. A part of the first wiring layer is connected to wiring 241a via titanium nitride 244 and tungsten 245 filled in through-hole 243 formed so as to penetrate interlayer insulating film 221, first interlayer insulating film 225, and second interlayer insulating film 232.

According to Embodiment 1, there can be provided a capacitor having lower electrode 229 of a crown structure comprising an outside face and an inner face leaving first interlayer insulating film 225 to form deep hole 226; having a first capacitor region having first dielectric 228 and first upper electrode 227 on the outside face; and having a second capacitor region having second dielectric 230 and second upper electrode 231. There can also be provided a capacitor of a crown structure wherein first upper electrode 227 is connected to second upper electrode 231 via conductor film 224; first conductor plug 236a, wiring 241 a, and second conductor plug 239a; and first upper electrode 227 is surely connected to second upper electrode 231.

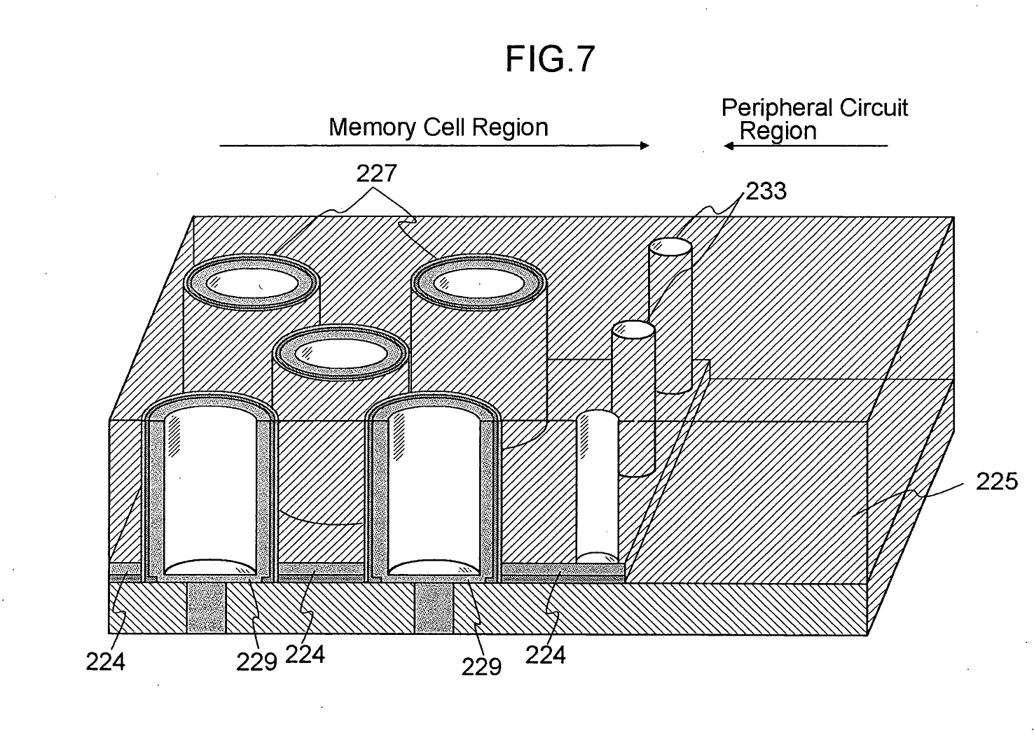

Next, a first method for fabricating a semiconductor device according to the present invention will be described referring to a series of process sectional views shown in FIGS. 5(A) to 5(P) and a bird's-eye view shown in FIG. 7. The description of steps before the step of fabricating the capacitor will be omitted.

First, as shown in FIG. 5(A), capacitive contact plugs 222 composed of phosphorus-doped silicon were formed in predetermined regions of interlayer insulating film 221 (hereinafter referred to as “lower interlayer insulating film”) composed of silicon oxide by a well-known method, and then, insulating film 223 composed of silicon nitride having a thickness of 50 nm was formed on the surface thereof by LPCVD (low pressure chemical vapor deposition). Further, conductor film 224 composed of phosphorus-doped silicon having a thickness of 100 nm was laminated thereon by LPCVD. The silicon nitride was formed from dichlorosilane (SiH₂Cl₂) and ammonia (NH₃) as material gases under the condition of 700° C. and 1.0 Torr. The phosphorus-doped silicon was formed from monosilane (SiH₄) and phosphine (PH₃) as material gases under the condition of 530° C. and 0.5 Torr. The phosphorus-doped silicon formed under a temperature condition of 530° C. was amorphous and had a high resistance. Therefore, for lowering the resistance by crystallization, heat treatment was performed at 700° C. for one minute in a nitrogen atmosphere. This heat treatment can be performed in another step.

Next, as shown in FIG. 5(B), conductor film 224 and insulating film 223 were removed from the region that became a peripheral circuit region by lithography and dry etching. Conductor film 224 composed of phosphorus-doped silicon was etched by chlorine-containing plasma, and insulating film 223 composed of silicon nitride was etched by fluorine-containing plasma.

Next, as shown in FIG. 5(C), first interlayer insulating film 225 composed of silicon oxide having a thickness of 1,500 nm was formed by plasma CVD using tetraethoxy silane (TEOS: Si(OC₂H₅)₄) and oxygen as material gases, then, the surface thereof was planarized by CMP (chemical mechanical polishing), and silicon film 246 having a thickness of 500 nm was formed and laminated thereon by CVD. Silicon film 246 was used as a hard mask when first interlayer insulating film 225 was subjected to dry etching.

Next, as shown in FIG. 5(D), deep holes 226 were opened in the predetermined location of first interlayer insulating film 225 by lithography and anisotropic dry etching to expose the surface of conductor film 224.

Specifically, silicon film 246 was subjected to anisotropic dry etching using a photo-resist pattern (not shown) formed by lithography as a mask. and then, first interlayer insulating film 225 was subjected to anisotropic dry etching using silicon film 246 as a mask. In the anisotropic dry etching of silicon film 246, chlorine-containing plasma consisting of the mixed gas of chlorine (Cl₂), hydrogen bromide (HBr), and oxygen (O₂) was used; and the pressure was 10 mTorr, and the plasma power was 100 W. In the anisotropic dry etching of first interlayer insulating film 225 composed of silicon oxide, fluorine-containing plasma consisting of the mixed gas of octafluorocyclopentane (C₅F₈), argon (Ar), and oxygen (O₂) was used; and the pressure was 100 mTorr, and the plasma power was 1,500 W. These conditions can be optionally changed.

Next, as shown in FIG. 5(E), conductor film 224 composed of phosphorus-doped silicon exposed on the bottoms of deep holes 226 was subjected to anisotropic dry etching using chlorine-containing plasma, then, insulating film 223 composed of silicon nitride was subjected to anisotropic dry etching using fluorine-containing plasma. As a result, the surface of capacitive contact plugs 222 and the sides of conductor film 224 are exposed. By this anisotropic dry etching, silicon film 246 used as the hard mask was simultaneously removed.

Next, as shown in FIG. 5(F), after cleaning the sides of conductor film 224, phosphorus-doped silicon film 227a having a thickness of 15 nm was formed on the entire surface.

Next, as shown in FIG. 5(G), anisotropic dry etching was performed using chlorine-containing plasma to remove the phosphorus-doped silicon film on the bottom of deep holes 226 and the surface of first interlayer insulating film 225. As a result, first upper electrode 227 composed of phosphorus-doped silicon was formed on the sidewalls of deep holes 226. First upper electrode 227 was connected to conductor film 224.

Next, as shown in FIG. 5(H), aluminum oxide film 228a having a thickness of 6 nm and phosphorus-doped silicon film 229a having a thickness of 15 nm were laminated. The aluminum oxide film was formed using atomic layer deposition (ALD). Trimethyl aluminum (TMA: Al(CH₃)₃) was used as the material gas, and ozone (O₃) was used as the oxidant. Basic steps of material feeding, exhaust, ozone feeding, and exhaust were made one cycle, and 60 cycles were repeated to form the film having a thickness of 6 nm. The pressure and the temperature in material feeding and ozone feeding were maintained at 0.5 Torr and 350° C., respectively. Since the process efficiency of film formation using ALD is extremely low, it is preferred to use a batch process that can process a plurality of substrates at a time. The conditions of ALD can be variously changed to the conditions other than those described above.

Next, as shown in FIG. 5(I), anisotropic dry etching was performed using chlorine-containing plasma to remove phosphorus-doped silicon film 229a and aluminum oxide film 228a at the bottom of deep holes 226 and the surface of first interlayer insulating film 225. As a result, first dielectrics 228 and outside lower electrodes 229b to be a part of lower electrodes were formed on the sidewalls of the deep holes. The surfaces of capacitive contact plugs 222 were exposed again.

Next, as shown in FIG. 5(J), after cleaning the surfaces of capacitive contact plugs 222 and the surfaces of outside lower electrodes 229b, phosphorus-doped silicon film 229c having a thickness of 15 nm was formed on the entire surface. Thereafter, the deep holes were filled with photo-resist 247. Photo-resist 247 was formed by applying a photo-resist on the entire surface, exposing the entire surface to a desired depth in the deep holes, and removing the exposed portions of the surface by developing treatment.

Next, as shown in FIG. 5(K), phosphorus-doped silicon film 229c on first interlayer insulating film 225 was removed by anisotropic dry etching, and photo-resist 247 filled in the deep holes was removed by oxygen plasma ashing. As a result, inside lower electrodes 229d to be a part of the lower electrode were formed. Lower electrode 229 was connected to capacitive contact plugs 222.

Next, as shown in FIG. 5(L), second dielectric 230 composed of aluminum oxide having a thickness of 6 nm was formed on the entire surface by ALD.

Next, as shown in FIG. 5(M), second upper electrode 231 composed of titanium nitride having a thickness of 30 nm was formed on the entire surface, and silicon oxide film 248 having a thickness of 200 nm was further formed on the entire surface by plasma CVD. Second upper electrode 231 was formed using titanium chloride (TiCl₄) and ammonia (NH₃) as material gases under conditions of a pressure of 1 Torr and a temperature of 550° C. Second upper electrode 231 is not limited to titanium nitride, but can be of other metal, or of a configuration wherein other metal is laminated by sputtering on titanium nitride having high coating property formed by CVD or ALD.

Next, as shown in FIG. 5(N), silicon oxide film 248, second upper electrode 231, and second dielectric 230 formed in the regions other than the memory cell region were removed by lithography and anisotropic dry etching. In the anisotropic dry etching of second upper electrode 231, a mixed gas of chlorine (Cl₂) and boron chloride (BCl₃) was used, and the pressure was 10 mTorr and the plasma power was 100 W. By this etching, second dielectric 230 was also removed at the same time.

Next, as shown in FIG. 5(O), second interlayer insulating film 232 composed of silicon oxide having a thickness of 500 nm was formed by plasma CVD, and the surface thereof was planarized by CMP.

Next, as shown in FIG. 5(P), by lithography and anisotropic dry etching, first through-hole 233 penetrating first interlayer insulating film 225 and second interlayer insulating film 232, and adjoining the memory cell region was formed, and the surface of conductor film 224 was exposed. Second through-hole 237 was formed in second interlayer insulating film 232 in the memory cell region to expose the surface of the second upper electrode. Although the first and second through-holes can be formed separately, they can be simultaneously formed, and simultaneous formation is more efficient. Through-holes located in the peripheral circuits can also be simultaneously formed.

Next, as shown in FIG. 4, titanium nitride and tungsten were formed on the entire surface so as to bury through-holes, and thereafter, titanium nitride and tungsten formed on second interlayer insulating film 232 were removed using CMP. As a result, first conductor plug 236a composed of titanium silicide 234, titanium nitride 235 and tungsten 236 was formed in first through-hole 233. Titanium silicide 234 can be formed by adding a step of supplying only titanium chloride in the initial stage of the step of forming titanium nitride using titanium chloride and ammonia. On the other hand, in second through-hole 237, second conductor plug 239a composed of titanium nitride 238 and tungsten 239 was formed.

Next, also as shown in FIG. 4, titanium nitride 240, aluminum 241 and titanium nitride 242 were laminated by sputtering to form wiring 241 a by lithography and anisotropic dry etching. As a result, first upper electrodes 227 that is connected to first conductor plug 236a via conductor film 224 can be connected to second upper electrode 231 that is connected to second conductor plug 239a using wiring 241a.

FIG. 7 shows a sketchy positional relation between first through-holes 233 and deep holes for forming capacitors using a bird's-eye view. For convenience, the second dielectric and the second upper electrode of the capacitor are omitted. Conductor film 224 connected to first upper electrodes 227 is formed so as to run off the memory cell region by the portion to form the first through-holes. Therefore, a plurality of first through-holes 233 can be disposed adjacent to the memory cell region so as to correspond to the locations of a plurality of second through-holes.

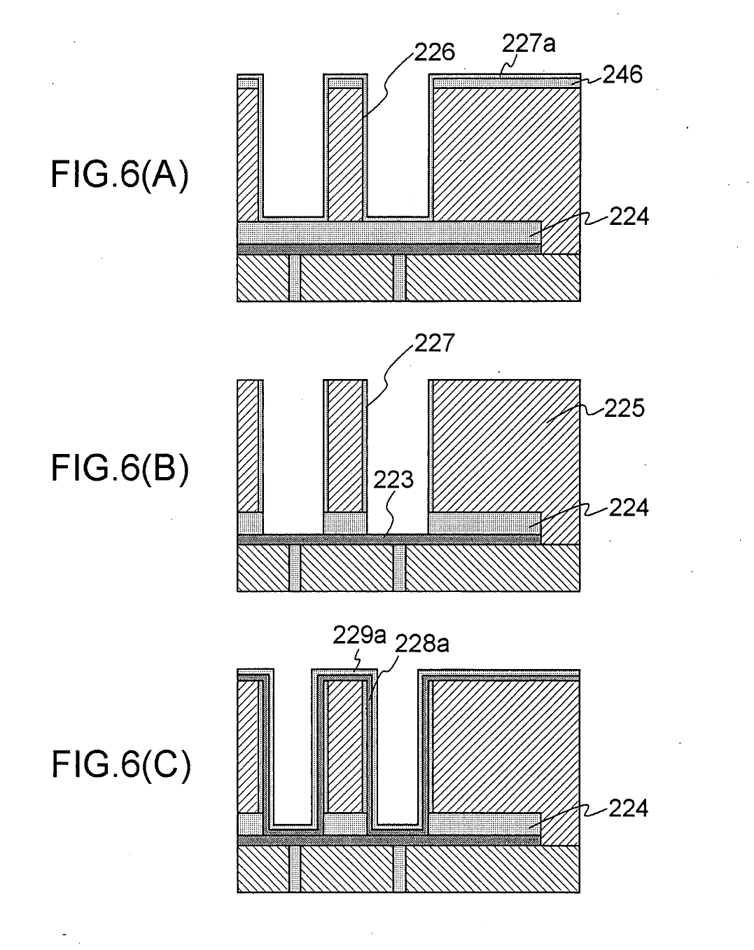

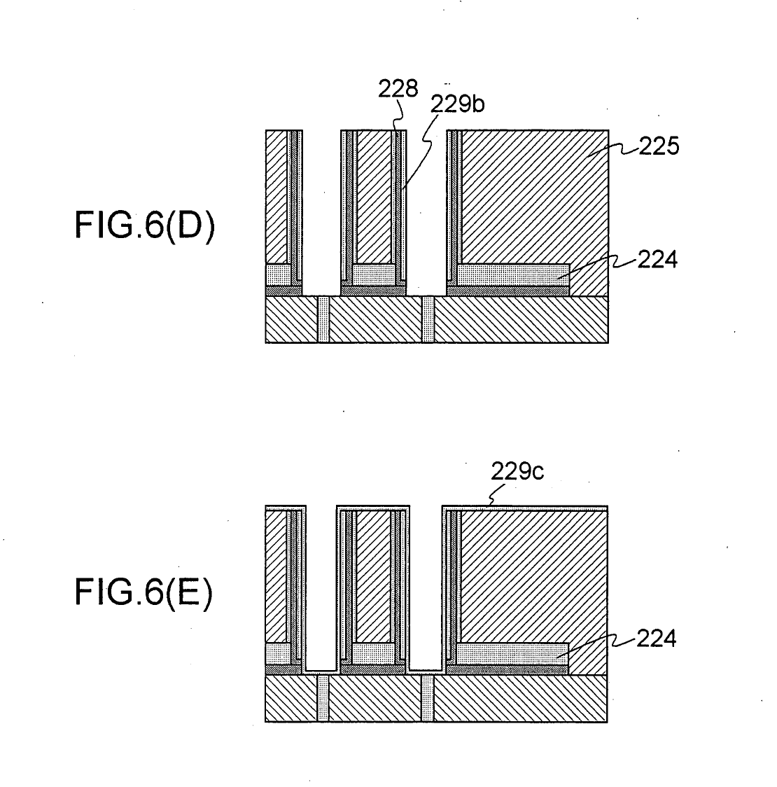

A second method for forming lower and upper electrodes will be described referring to FIG. 6.

FIG. 6(A) shows a step continuing the step shown in FIG. 5(D). In the first fabricating method, after the step shown in FIG. 5(D), conductor film 224 exposed at the bottom of deep holes 226 was removed by anisotropic dry etching. In the second fabricating method, after cleaning the surface of conductor film 224, phosphorus-doped silicon film 227a was formed on the entire surface.

Next, as shown in FIG. 6(B), using anisotropic dry etching, phosphorus-doped silicon film 227a and silicon film 246 used as the hard mask on the first interlayer insulating film, and phosphorus-doped silicon films 226 and 224 exposed at the bottoms of the deep holes were removed. As a result, first upper electrodes 227 were formed on the sidewalls of the deep holes, and first upper electrodes 227 were connected to the upper surface of conductor film 224. Insulating film 223 composed of silicon nitride was exposed on the bottom of the deep holes.

Next, as shown in FIG. 6(C), aluminum oxide film 228a to be a first dielectric and phosphorus-doped silicon film 229a to be an outside lower electrode are formed on the entire-surface.

Next, as shown in FIG. 6(D), using anisotropic dry etching, phosphorus-doped silicon film 229a and aluminum oxide film 228a formed on the upper surface of first interlayer insulating film 225; and phosphorus-doped silicon film 229a, aluminum oxide film 228a, and insulating film 223 formed on the bottoms of the deep holes were removed. As a result, first dielectrics 228 and outside lower electrodes 229b were formed, and the surfaces of capacitive contact plugs 222 were exposed on the bottoms of the deep holes.

Next, as shown in FIG. 6(E), after cleaning the surfaces of capacitive contact plugs 222 and the surfaces of outside lower electrodes 229b, phosphorus-doped silicon film 229c to be an inside lower electrode was formed. Thereafter, the process returned to the step shown in FIG. 5(J), and through the same steps, a capacitor can be formed.

In the first fabricating method, since the surfaces of capacitive contact plugs 222 are undergone a total of three times of anisotropic dry etching in steps shown in FIGS. 5(E), 5(G) and 5(I), the drop from the surface of lower interlayer insulating film 221 may increase; however, in the second fabricating method, since the surfaces of capacitive contact plugs 222 are undergone anisotropic dry etching only once in the step of FIG. 6(D), there is the effect of reducing the drop from the surface of lower interlayer insulating film 221.

As described above, according to the configuration of the present invention, since capacitors having a crown structure can be formed in deep holes formed in an insulating film, the removal of the insulating film is not required. Therefore, pair-bit defect caused by the contact of adjoining lower electrodes with each other due to the destruction of the lower electrodes can be avoided.

Furthermore, since capacitors having a crown structure are formed in deep holes, about twice as much capacity of the capacitor can be obtained compared with a simple deep-hole capacitor that does not use the outside surface of a lower electrode.

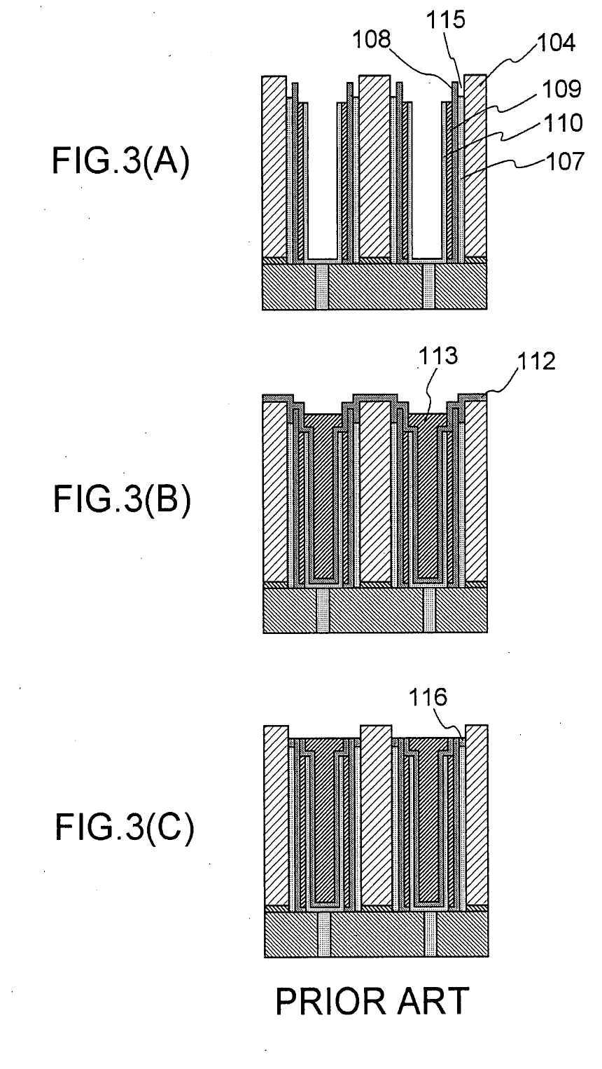

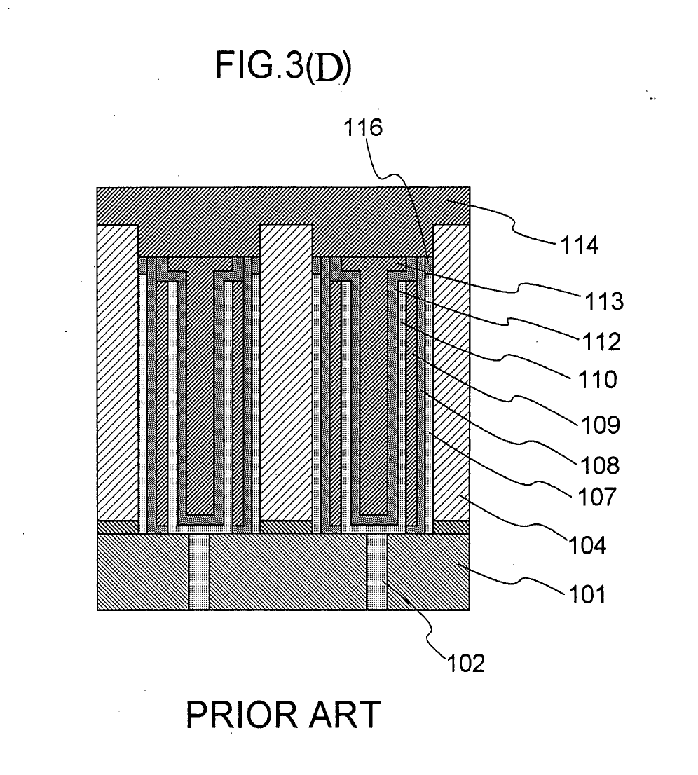

Therefore, the depth of the deep holes, which was required to be about 3 μm to achieve a desired capacity by a capacitor having a simple deep-hole structure, can be halved to about 1.5 μm, and the difficulty of dry etching for forming the deep holes can be avoided. Furthermore, since the first upper electrodes are connected to the second upper electrode via through-holes opened in the first interlayer insulating film adjoining the memory cell region, the problem of difficulty in connecting the first upper electrodes to the second upper electrode as described referring to FIG. 3 can be avoided.

In the above-described embodiments, since lower electrode 229 is formed using phosphorus-doped silicon, HSG (hemispherical silicon grains) can be formed on the surface of the exposed lower electrode in the step shown in FIG, 5(K), to expand the area and increase the capacity. Although aluminum oxide was used as the dielectric, hafnium oxide or tantalum oxide formed by ALD can also be used. While the dielectric constant of aluminum oxide is 9, those of hafnium oxide and crystallized tantalum oxide are 25 and 60, respectively; therefore, the capacity can be increased by the improvement of permittivity.

Also in the above-described embodiments, although conductor film 224, first upper electrodes 227, and lower electrode 229 were formed of phosphorus-doped silicon, the present invention is not limited thereto, but titanium nitride or metals such as tungsten and ruthenium can also be used. For example, when metals are used for conductor film 224 and first upper electrodes 227, the formation of titanium silicide film 234 is not required. Furthermore, when these are composed of such metals, compared with the case when these are composed of phosphorus-doped silicon, the capacity per unit area can approximately be doubled. By combining the above-described dielectric having high permittivity and lower electrode materials of these metals, capacity can be significantly elevated. In addition, when metals are used for electrodes, heat treatment at about 700° C. required for the crystallization of phosphorus-doped silicon is not required, and the effect of stress from the electrodes to the dielectric can be reduced and leakage current can be decreased.

What is claimed is:

1. A semiconductor device having a memory cell region that comprises a plurality of capacitors provided in a deep hole formed in a first interlayer insulating film,
wherein said capacitor includes a lower electrode having a crown structure composed of an outer wall face and an inner face, a first upper electrode facing the outer wall face of said lower electrode, a dielectric and a second upper electrode extending from the inner face of said lower electrode to the surface other than said deep hole, and
wherein said first upper electrode is connected to said second. upper electrode via at least a first conductor plug that buries a first through-hole formed in said first interlayer insulating film adjacently to said memory cell region.

2. The semiconductor device according to claim 1,
wherein said second upper electrode is connected to said first upper electrode by:
connecting said second upper electrode via a second conductor plug that buries a second through-hole provided in a second interlayer insulating film that covers said second upper electrode to wiring provided on said second interlayer insulating film; and
connecting said first upper electrode to a conductor film located at the bottom of said first interlayer insulating film, said conductor film being connected to the first conductor plug that buries the first through-hole formed in said first interlayer insulating film on said conductor film and said second interlayer insulating film laminated on said first interlayer insulating film, and said first conductor plug being connected to said wiring provided on said second interlayer insulating film.

3. The semiconductor device according to claim 1, wherein said conductor film located at the bottom of said first interlayer insulating film is extended from said memory cell region by the area of a region for forming said first through-hole.

4. The semiconductor device according to claim 1, wherein said lower electrode, said first upper electrode, said conductor film located at the bottom of said first interlayer insulating film, said second upper electrode, said first conductor plug, and said second conductor plug are composed of one or a plurality of materials selected from a group consisting of conductive silicon, metals, and metal compounds.

5. A method for fabricating a semiconductor device having a memory cell region that comprises a plurality of capacitors provided in a deep hole formed in a first interlayer insulating film, including a lower electrode, a dielectric, and an upper electrode, at least comprising steps of:
(1) forming contact plugs in a lower interlayer insulating film at a predetermined location of a memory cell region;
(2) sequentially depositing an insulating film and a conductor film on said lower interlayer insulating film;
(3) removing said insulating film and said conductor film located on the area other than the memory cell region and the adjacent region of said memory cell region;
(4) forming said first interlayer insulating film on the entire surface, and opening a deep hole in said first interlayer insulating film at a predetermined location of the memory cell region to expose the sides of said conductor film and the surfaces of said contact plugs;
(5) forming a first upper electrode on the sidewall of said deep hole so that said first upper electrode is connected to the sides of said conductor film;
(6) forming a first dielectric on the sidewall of said deep hole on which said first upper electrode has been formed;
(7) forming a lower electrode having a crown structure on the inner surface of said deep hole on which said first dielectric has been formed so that said lower electrode is connected to said contact plugs;
(8) forming a second dielectric and a second upper electrode on the inner surface of the deep hole on which the lower electrode has been formed;
(9) removing said second upper electrode around the memory cell region;
(10) forming a second interlayer insulating film on the entire surface;
(11) forming a second through-hole in said second interlayer insulating film at a predetermined location of the memory cell region to expose the surface of said second upper electrode;
(12) forming a first through-hole in said second and first interlayer insulating films at a predetermined location of said adjacent region of the memory cell region to expose the surface of said conductor film;
(13) forming a first conductor plug filling said first through-hole, and a second conductor plug filling said second through-hole; and
(14) forming wiring on said second interlayer insulating film to connect said first conductor plug to said second conductor plug.

6. The method for fabricating a semiconductor device according to claim 5, wherein the step of exposing the surface of said contact plugs in said step (4) comprises steps of:
(1) opening a deep hole at a predetermined location of the memory cell region, and exposing the surface of said conductor film;
(2) forming said first upper electrode on the inner surface of said deep hole on which the surface of said conductor film is exposed and removing said first upper electrode and said conductor film at the bottom of said deep hole to expose the surface of said insulating film; and
(3) forming said first dielectric on the inner surface of said deep hole on which said first upper electrode has been formed and the surface of said insulating film has been exposed; and removing said first dielectric and said insulating film at the bottom of the deep hole to expose said contact plugs.

7. The method for fabricating a semiconductor device according to claim 5, wherein said step (11) comprises a step which is simultaneously carried out with step (12).

8. The method for fabricating a semiconductor device according to claim 5, wherein said adjacent region of the memory cell region in which the connection of said conductor film with the first conductor plug is formed is extended from said memory cell region by the area of a region for forming said first through-hole.

9. The method for fabricating a semiconductor device according to claim 5, wherein said lower electrode, said first upper electrode, said conductor film, said second upper electrode, said first conductor plug, and said second conductor plug are composed of one or a plurality of materials selected from a group consisting of conductive silicon, metals, and metal compounds, respectively.
